(19) United States
(12) Patent Application Publication
(10) Pub. No.: US 2019/0252321 A1
(43) Pub. Date: Aug. 15, 2019

(54) INTERCONNECTOR WITH BUNDLED INTERCONNECTS

(71) Applicant: Intel Corporation, Santa Clara, CA (US)

(72) Inventors: Henning Braunisch, Phoenix, AZ (US); Kemal Aygun, Tempe, AZ (US); Yidnekachew S. Mekonnen, Chandler, AZ (US)

(21) Appl. No.: 16/335,029

(22) PCT Filed: Sep. 28, 2016
(86) PCT No.: PCT/US2016/054235

§ 371 Date: Mar. 20, 2019

(51) Int. Cl. H01L 23/538; H01L 23/66; H01L 25/065

(52) U.S. Cl. CPC H01L 23/5381; H01L 23/66; H01L 25/065; H01L 23/5385; H01L 23/5386; H01L 23/5384

(57) ABSTRACT

Disclosed is a signaling system. The signaling system may comprise a transmitter, a receiver, and a package interconnect. The transmitter may be configured to transmit M signals. The receiver may be configured to receive the M signals. The package interconnect may include a bundle of N wires electrically connecting the transmitter and the receiver. During operation, the N wires may be electromagnetically coupled with each other and the M signals may travel between the transmitter and the receiver on the bundle of N wires.

### TECHNICAL FIELD

Embodiments described generally herein relate to microelectronic packages. More particularly, embodiments described generally herein relate to electrical interconnectors within microelectronic packages.

### BACKGROUND

Microelectronics generally include a central processing unit (CPU). In order to enhance performance, CPU products are increasingly integrating multiple dies within the CPU package in a side-by-side or other multi-chip module (MCM) format. An embedded multi-die interconnect bridge (EMIB) is a way to electrically connecting multiple dies within a microelectronic package.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a portion of a microelectronics package in accordance with some embodiments disclosed herein.

FIG. 2 illustrates a wiring schematic for a signaling system in accordance with some embodiments disclosed herein.

FIGS. 3A-3D illustrate interconnect stack ups in accordance with some embodiments disclosed herein.

FIGS. 4A-4F illustrate interconnect stack ups in accordance with some embodiments disclosed herein.

FIGS. 5A-5D illustrate interconnect stack ups in accordance with some embodiments disclosed herein.

FIGS. 6A and 6B illustrate interconnect stack ups in accordance with some embodiments disclosed herein.

FIG. 7 illustrates a method for manufacturing a signaling system in accordance with some embodiments disclosed herein.

FIG. 8 illustrates a system level diagram in accordance with some embodiments disclosed herein.

### DETAILED DESCRIPTION

Embedded multi-die interconnect bridge (EMIB) is a dense multichip packaging solution for interconnecting dies on a package. Non-limiting examples of dies of interest include central processing units (CPUs), graphics processing units (GPUs), field programmable gate arrays (FPGAs), high-speed transceivers, and stacked dynamic random-access memory (DRAM) such as High-Bandwidth Memory (HBM). Instead of a interposer, an EMIB package may utilize localized silicon bridges that may have lower costs and do not degrade off-package interconnects by avoiding through-silicon vias (TSVs).

As physical interconnect density is increased signal integrity may decrease due to an increase in crosstalk, which can limit an achievable bandwidth density. As disclosed herein, a combined tight bundling of signal wires, potentially across multiple adjacent metal layers, with an active crosstalk cancellation technique, such as, for example, multimode signaling, can be implemented in the on-die transmitter and/or receiver portions of a signaling system. This enables a continued increase of bandwidth density with increasing physical interconnect density.

As disclosed herein, signals on an interconnect bridge may be grouped into bundles of wires (sometimes called traces), thereby increasing physical interconnect density. At the same time, on-die crosstalk cancellation circuits can be used to recover the bundled signals with little or sufficiently small crosstalk at the receiver, thereby maximizing the achieved bandwidth density. This can reduce dense routing area and the bridge size and the bridge layer count, and minimize the need for any on-die fan-out routing.

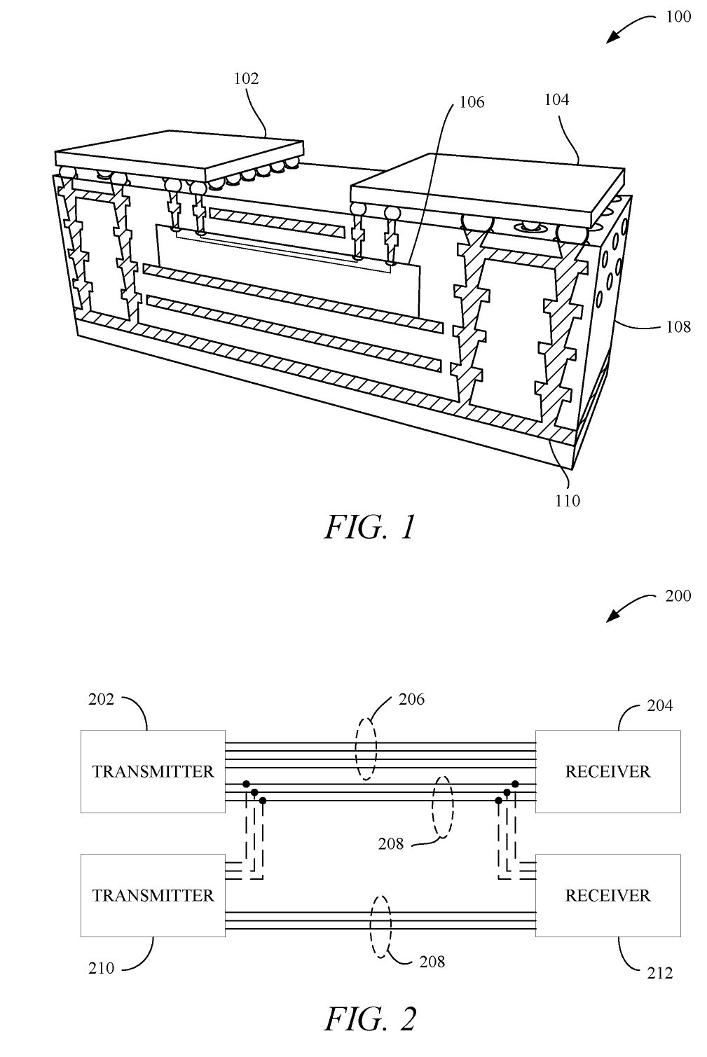

Turning now to the figures, FIG. 1 illustrates a microelectronic package 100. The microelectronic package 100 can include a first die 102, a second die 104, a package interconnect 106, and substrate 108. As shown in FIG. 1, the microelectronic package 100 can also include electrical connections 110 that can be used to power the first die 102 and the second die 104 and allow signals to pass between the first die 102 and the second die 104. The electrical connections 110 can also be used to provide ground references. The package interconnect 106 can be surrounded by, or embedded in, the substrate 108. In addition, the package interconnect 106 can include a silicon bridge, a silicon interposer, a fan-out wafer level package interconnect, a fan-out panel level package interconnect, and an organic dense multichip package interconnect.

A silicon bridge may refer to EMIB technology. For example, small pieces of silicon may be embedded in an organic package substrate and provide high-density interconnect between dies on the package. An example of a silicon interposer is TSMC's chip-on-wafer-on-substrate (CoWoS). Active dies may be assembled on a large piece of silicon that provides dense interconnect between the dies. As opposed to a silicon bridge, a silicon interposer may have through-silicon vias (TSVs) to provide off-package interconnects.

An example for a fan-out wafer level package (FOWLP) may be a TSMC's integrated fan-out (InFO) package. Active dies may be molded into a reconstituted wafer format and interconnected by relatively dense redistribution layers (RDLs). Fan-out panel level packaging (FOPLP) arranges the embedded dies in a panel format rather than in wafer format, in order to achieve lower cost. An organic dense multichip package as disclosed herein is a multichip package with organic interlayer dielectric material and a wiring density of greater than 100 IO/mm/layer. Different from FOWLP the dies are not embedded, so this may be suitable for higher performance applications.

FIG. 2 illustrates a wiring schematic for a signaling system 200, such as part of the microelectronics package 100. The signaling system 200 can include a transmitter 202, a receiver, 204, a bundle of N wires 206, and a bundle of W wires 208. The bundle of N wires 206 and the bundle of W wires 208 can be embedded within the package interconnect 106. In addition, the signaling system 200 can include a second transmitter 210 and a second receiver 212. The bundle of W wires 208 can connect the second transmitter 210 and the second receiver 212. While FIG. 2 shows the number of transmitters equals the number or receivers, the number of receivers and the number of receivers does not have to be equal. For example, the signaling system 200 may have one transmitter and two receivers. Stated generally, the number of transmitters, I, and the number of receivers, J, can be any positive integers, where I and J do not have to be equal. The transmitters and receivers can be part of dies, such as the first die 102 and the second die 104.

During operation, the transmitters 202 and 210 can modulate a signal into a plurality of signals that can be transmitted on a bundle of wires and received by the receivers 204 and 212. For example, the transmitter 202 can modulate a single signal into M signals that can be transmitted to the receiver 204 on the bundle of N wires 206. In addition, the transmitter 210 can modulate a single signal into X signals and transmit the X signals to the receiver 212 on the bundle of W wires 208.

The modulated signal can be transmitted on all of the wires within a bundle or a subset of the bundles of wires. For example, the bundle of N wires may include 100 wires and a single signal may be modulated into 50 signals that are transmitted on 50 of the 100 wires. Stated generally, the number of wires within a bundle of wires is greater than 3 and the number of signals is greater than 2. In addition, often the number of signals (M or X) is less than or equal to the number of wires within a bundle of wires (N or W).

For example, the number of wires (N or W) can range from 3 to 30 to 300 to 3,000 or more. The number of signals (M or X) can range from 2 to 20 to 200 to 2,000 or more. However, the number of signals may not exceed the number of wires.

The wires within a bundle of wires are spaced close together to promote crosstalk between the signals carried on each of the wires within the bundle of wires. Stated another way, the wires within a bundle of wires are spaced in close proximity to one another to promote electromagnetic coupling of the wires within the bundle of wires. For example, if the edge-to-edge spacing between wires is made less than two times the line width within well-defined bundles over extended lengths of routing then bandwidth density can be increase by utilizing crosstalk as disclosed herein. The spacing between bundles of wires can be maximized to avoid crosstalk between individual bundles of wires.

Because the design parameters of the bundles of wires are known, the receivers 204 and 212 can receive the plurality of signals and demodulate the signals. For example, the length of the wires within a bundle of wires, the spacing between the wires within a bundle of wires, the degree of electromagnetic coupling, etc. may be known for each of the bundle of wires and as result, the receiver 204 and 212 can be programmed to use this information to demodulate the M or W signals into a single signal.

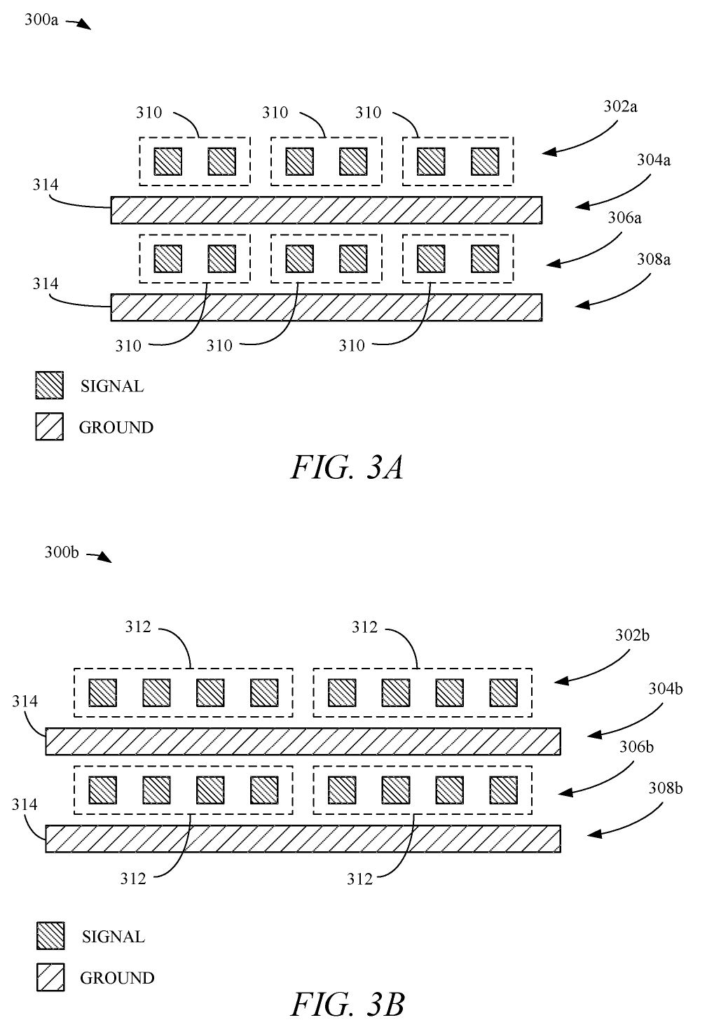

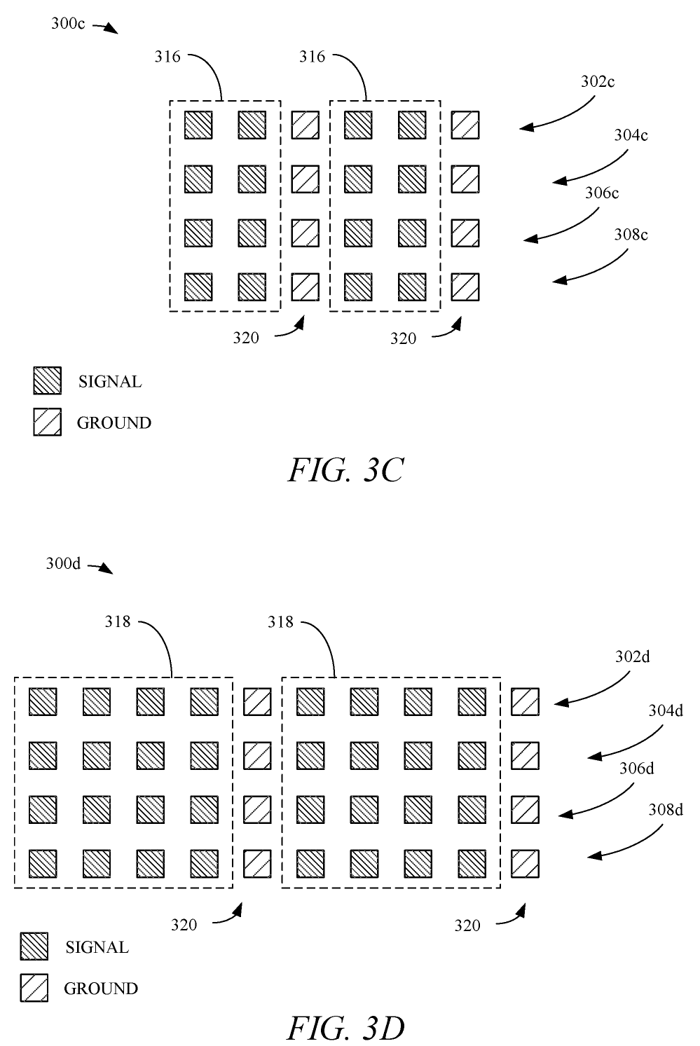

FIG. 3A-3D illustrate interconnect (e.g., a silicon bridge) stack up 300a-300d configurations in accordance with some embodiments disclosed herein. As shown in FIGS. 3A-3D, the interconnect stack ups 300a-300d can each include a first metal layer 302a-302d, a second metal layers 304a-304d, a third metal layer 306a-306d, and a fourth metal layer 308a-308d. In other words, the various stack ups in FIGS. 3A-3D each include four metal layers. Dashed lines within FIGS. 3A-3D indicate bundling of wires. As shown in FIGS. 3A-3D, the number of bundles of wires can vary and the number of wires within a bundle of wires can vary.

As disclosed herein, a bundle of wires can carry a plurality of signals, (i.e., a bundle of N wires can carry up to N signals) and on-die crosstalk cancellation circuits are designed to recover these N signals with little or sufficiently small crosstalk at the receiver. FIGS. 3A and 3B illustrate bundles of signal wires 310 and 312 that are spaced apart laterally and are separated by a ground plane 314 to control crosstalk between the various bundles of wires. As shown in FIGS. 3C and 3D, ground planes 314 can be eliminated and bundles of signal wires 316 and 318 can be separated laterally by ground wires 320. Ground planes 314 and ground wires 320 can also serve as signal current return paths.

During fabrication of the bundle of wires, the spacing of the individual wires relative to one another can be a trace width (TW) and the bundle-to-bundle spacing can be two times the TW (2 TW). The signal-to-ground wire spacing can also be TW. Using the various spacing parameters, an interconnect density, D, can be defined as the number of signals (input/output (IO)) per interconnect width and a number of metal layers used. Mathematically, D can be represented as:

$$D = \frac{\frac{Number of Signals}{Interconnect Width}}{Number of Layers} = \frac{Number of S ignals}{( Interconnect Width ) ( Number of Layers )} \qquad Equation 1$$

Using the above definition of an interconnect density, a standard interconnect with four layers that does not use wire bundling as disclosed herein and where the wire spacing, SP, can be two times the TW can have an interconnect density of:

$$D = \frac{2 IO}{( TW + SP ) ( Number of Layers )} = \frac{2 IO}{12 TW} = 0.17 \frac{IO}{TW} \qquad Equation 2$$

Using Equation 1, the interconnect density for FIGS. 3A-3D are 0.2 IO/TW, 0.22 IO/TW, 0.33 IO/TW, and 0.4 IO/TW, respectively. As shown in FIGS. 3A-3D, the interconnect density increases as the number of wires within a bundle increases. In addition, as shown in FIGS. 3A-3D, the number of signal wires within a bundle can range from 2 to 16 and any number of ground references can be used.

In addition, the configuration of the various bundles of wires can vary from 1 by 2 configurations to 4 by 4 configurations. However, the configuration of the various bundles can be n by m, where n and m are positive integers. In addition, various bundle configurations can be mixed within an interconnect. For example, one bundle of wires may have a 1 by 2 configuration and another bundle of wires may have a 2 by 4 configuration.

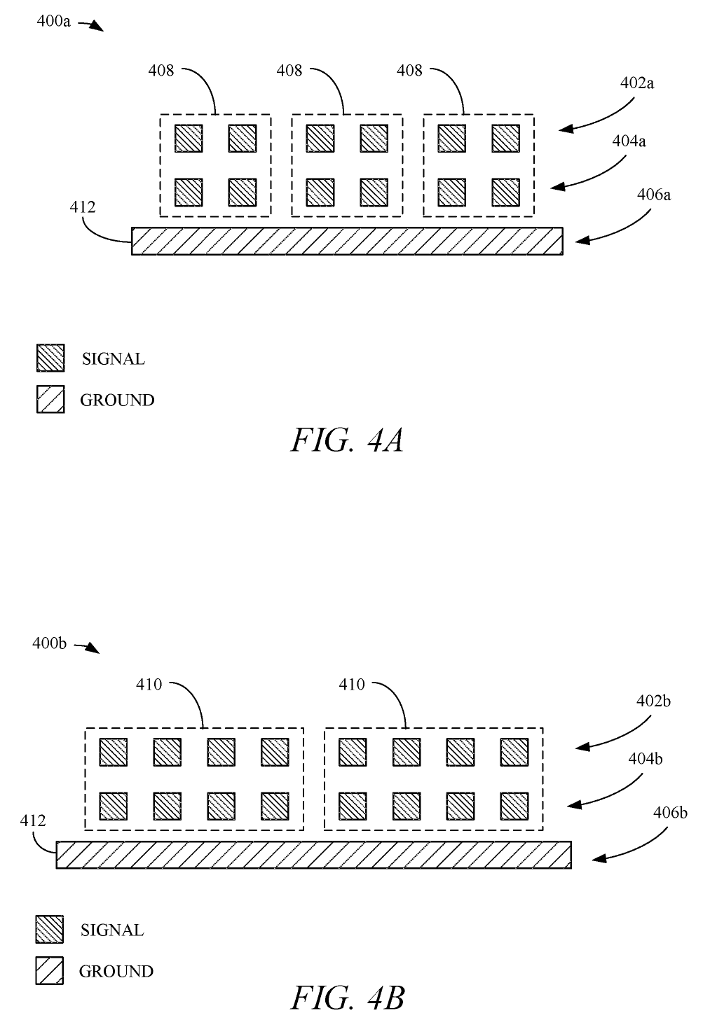

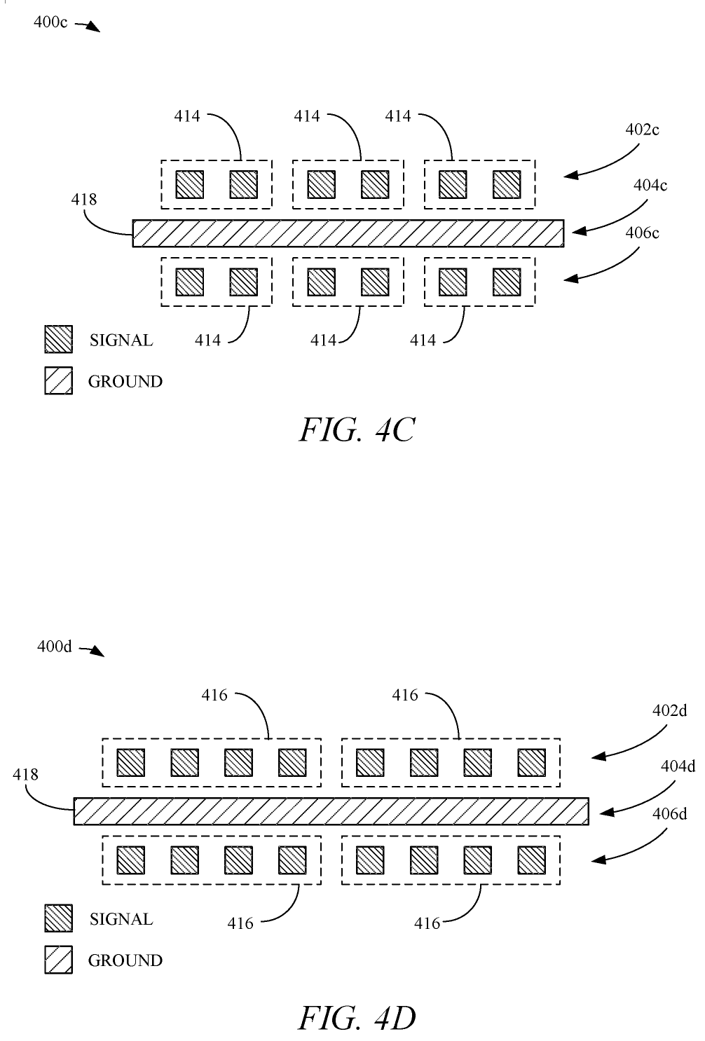

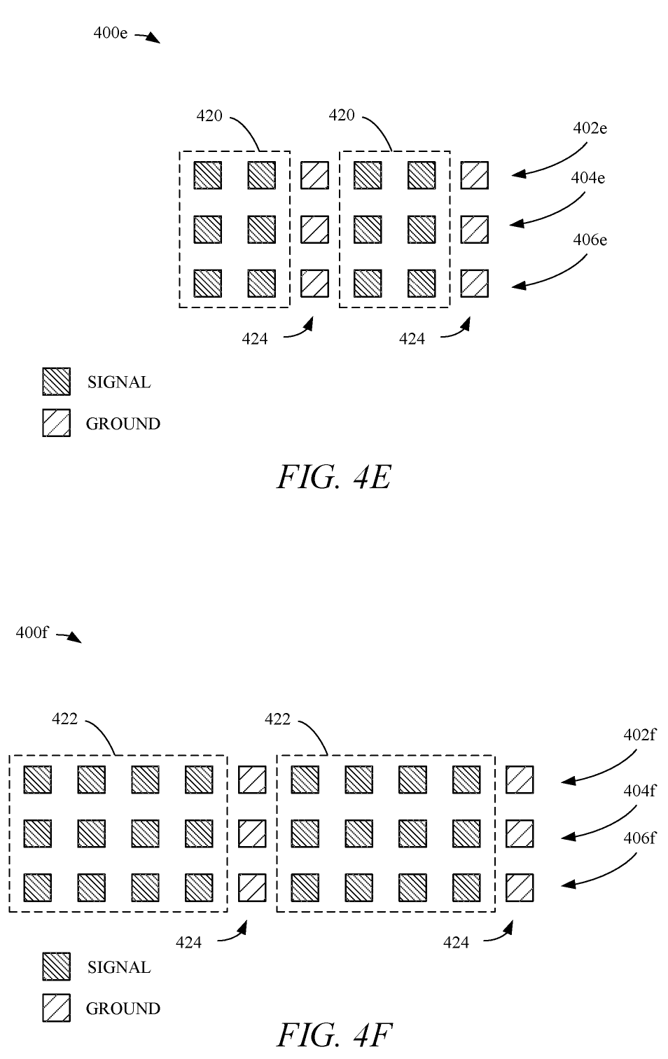

FIGS. 4A-4F illustrate interconnect stack up 400a-400f configurations in accordance with some embodiments disclosed herein. As shown in FIGS. 4A-4F, the interconnect stack ups 400a-400f can each include a first metal layer 402a-402f, a second metal layer 404a-404f, and a third metal layer 406a-406f In other words, the various stack ups in FIGS. 4A-4F each include three metal layers. Dashed lines within FIGS. 4A-4F indicate bundling of wires. As shown in FIGS. 4A-4F, the number of bundles of wires can vary and the number of wires within a bundle of wires can vary.

As disclosed herein, a bundle of wires can carry a plurality of signals (i.e., a bundle of N wires can carry up to N signals) and on-die crosstalk cancellation circuits are designed to recover these N signals with little or sufficiently small crosstalk at the receiver. As shown in FIGS. 4A and 4B, bundles of signal wires 408 and 410 can be arranged above a ground plane 412. As shown in FIGS. 4C and 4D, bundles of signal wires 414 and 416 are spaced apart laterally and are separated by a ground plane 418 to control crosstalk between the various bundles of wires. As shown in FIGS. 4E and 4F, ground planes 412 and 418 can be eliminated and bundles of signal wires 420 and 422 can be separated laterally by ground wires 424. Ground planes 412, 418, and 424 can also serve as signal current return paths.

The interconnect density for each configuration shown in FIGS. 4A-4F can be calculated using Equation 1. Using Equation 1, the interconnect density for FIGS. 4A-4F are 0.27 IO/TW, 0.30 IO/TW, 0.27 IO/TW, 0.30 IO/TW, 0.33 IO/TW, and 0.4 IO/TW, respectively. In addition, as shown in FIGS. 4A-4F, the number of signal wires within a bundle can range from 2 to 12. Any number of ground references can be used.

As shown, the configuration of the various bundles of wires can vary from 1 by 2 configurations to 3 by 4 configurations. However, the configuration of the various bundles can be n by m, with n and m being positive integers. In addition, various bundle configurations can be mixed within an interconnect. For example, one bundle of wires may have a 1 by 2 configuration and another bundle of wires may have a 3 by 4 configuration.

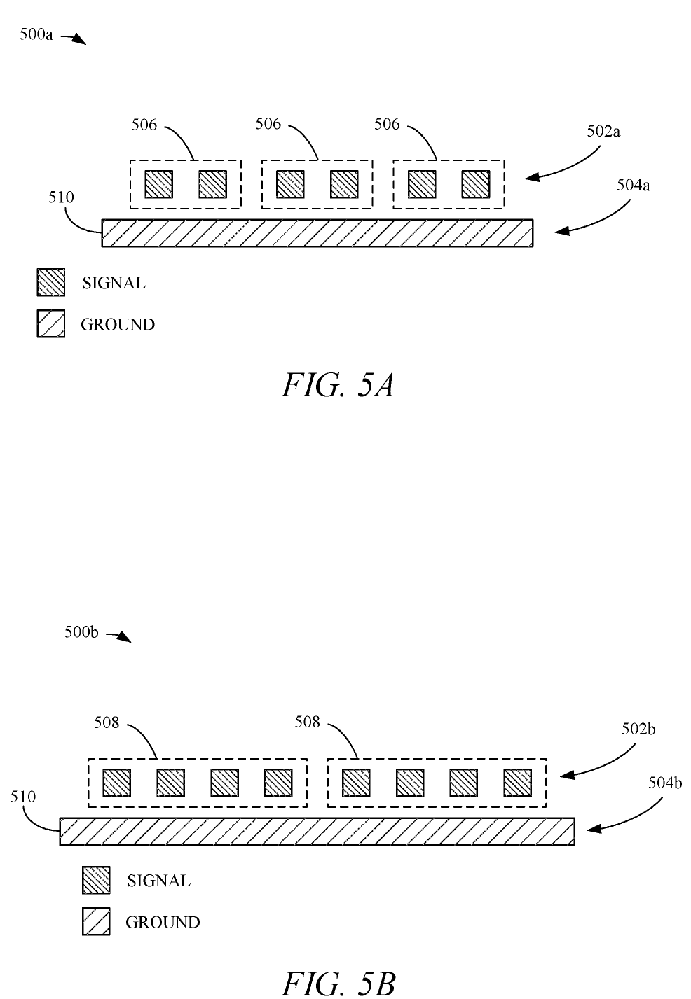

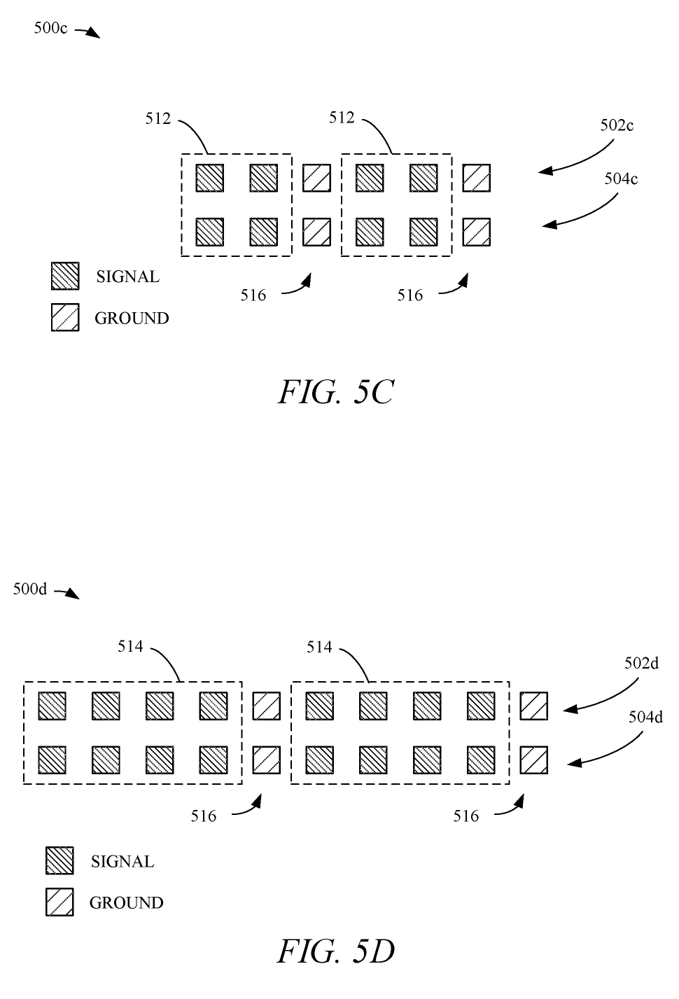

FIG. 5A-5D illustrate interconnect stack up 500a-500d configurations in accordance with some embodiments disclosed herein. As shown in FIGS. 5A-5D, the interconnect stack ups 500a-500d can each include a first metal layer 502a-502d and a second metal layer 504a-504e. In other words, the various stack ups in FIGS. 5A-5D each include two metal layers. Dashed lines within FIGS. 5A-5D indicate bundling of wires. As shown in FIGS. 5A-5D, the number of bundles of wires can vary and the number of wires within a bundle of wires can vary.

As shown in FIGS. 5A and 5B, bundles of signal wires 506 and 508 can be arranged above a ground plane 510. As shown in FIGS. 5C and 5D, bundles of signal wires 512 and 514 are spaced apart laterally and are separated by ground wires 516 to control crosstalk between the various bundles of wires. Ground planes 510 and ground wires 516 can serve as signal current return paths.

The interconnect density for each configuration shown in FIGS. 5A-5D can be calculated using Equation 1. Using Equation 1, the interconnect density for FIGS. 5A-5D are 0.2 IO/TW, 0.22 IO/TW, 0.33 IO/TW, and 0.4 IO/TW, respectively. As shown in FIGS. 5A-5D, the interconnect density increases as the number of wires within a bundle increases. In addition, as shown in FIGS. 5A-5D, the number of signal wires within a bundle can range from 2 to 8. Any number of ground references can be used.

As shown, the configuration of the various bundles of wires can vary from 1 by 2 configurations to 2 by 4 configurations. However, the configuration of the various bundles can be n by m, with n and m being positive integers. In addition, various bundle configurations can be mixed within an interconnect. For example, one bundle of wires may have a 1 by 2 configuration and another bundle of wires may have a 2 by 4 configuration.

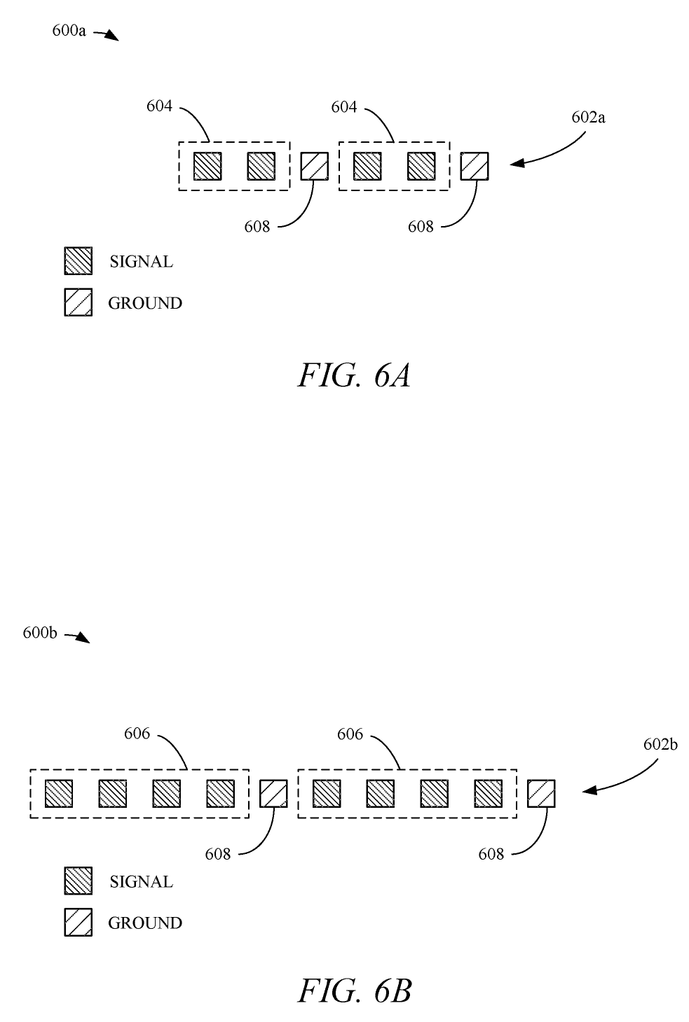

FIGS. 6A and 6B illustrate interconnect stack up 600a and 600b configurations in accordance with some embodiments disclosed herein. As shown in FIGS. 6A-6B, the interconnect stack ups 600a and 600b can each include a first metal layer 602a and 602b, or a single metal layer. Dashed lines within FIGS. 6A and 6B indicate bundling of wires.

As shown in FIGS. 6A and 6B, bundles of signal wires 604 and 606 can be arranged spaced apart laterally and are separated by ground wires 608 to control crosstalk between the various bundles of wires. Ground wires 608 can serve as signal current return paths.

The interconnect density for each configuration shown in FIGS. 6A and 6B can be calculated using Equation 1. Using Equation 1, the interconnect density for FIGS. 6A and 6B are 0.33 IO/TW, and 0.4 IO/TW, respectively. As shown in FIGS. 6A and 6B, the interconnect density increases as the number of wires within a bundle increases.

As shown, the configuration of the various bundles of wires can vary from 1 by 2 configurations to 1 by 4 configurations. However, the configuration of the various bundles can be 1 by m. In addition, various bundle configurations can be mixed within an interconnect. For example, one bundle of wires may have a 1 by 2 configuration and another bundle of wires may have a 1 by 4 configuration.

The various bundling configurations disclosed herein can be combined and are not limited to any particular configurations. For example, the single signal and ground layer configuration shown in FIG. 6A can be combined with the bundling and ground reference configuration shown in FIG. 4A to form a four layer combination having differing bundles of wires and ground configuration.

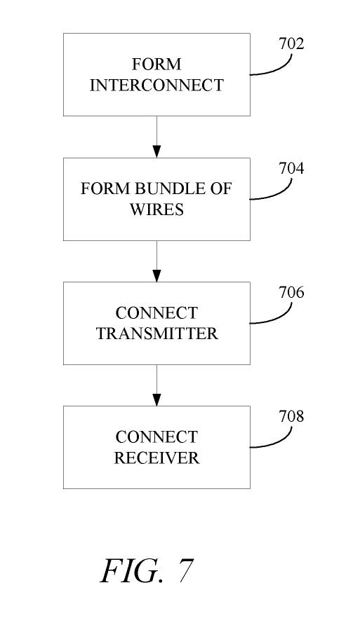

FIG. 7 illustrates a method 700 for manufacturing a signaling system, such as signaling system 200, in accordance with some embodiments disclosed herein. The method 700 can begin at stage 702 where a package interconnect is formed. The package interconnect can be formed using back end of line (BEOL), middle of line (MOL), or front end of line (FEOL) processes. For example, during a BEOL process the various metal layers and insulators can be formed.

From stage 702, the method 700 can proceed to stage 704 where bundles of wires can be formed. For example, a substrate can be etched and a copper conductor deposited within the substrate. In addition to forming a single bundle of wires, multiple bundles of wires can be formed at stage 704. For example a bundle of N wires can be formed and a bundle of W wires can be formed. Stages 702 and 704 can be formed simultaneously or in series. In addition, the order of stages 702 and 704 can be reversed.

From stage 704 (or 702), the method 700 can proceed to stage 706 where a transmitter can be connected to a bundle of N wires. As detailed herein, the transmitter can be part of a die, such as the first die 102. In addition to the bundle of N wires, the transmitter can be connected to a plurality of bundle of wires. For example, the transmitter can be connected to a bundle of N wires and a bundle of W wires. In addition, more than one transmitter can be utilized as disclosed herein. For instance a first transmitter can be connected to a bundle of N wires and a second transmitter can be connected to a bundle of W wires. The transmitter can be programmed to modulate a single signal into a plurality of signals as described herein.

From stage 706, the method 700 can proceed to stage 708 where a receiver can be connected to a bundle of wires. As detailed herein, the receiver can be part of a die, such as the second die 104. In addition to the bundle of N wires, the receiver can be connected to a plurality of bundle of wires. For example, the receiver can be connected to a bundle of N wires and a bundle of W wires. In addition, more than one receiver can be utilized as disclosed herein. For instance a first receiver can be connected to a bundle of N wires and a second receiver can be connected to a bundle of W wires. The receiver can be programmed to demodulate the plurality of signals into a single signal as described herein.

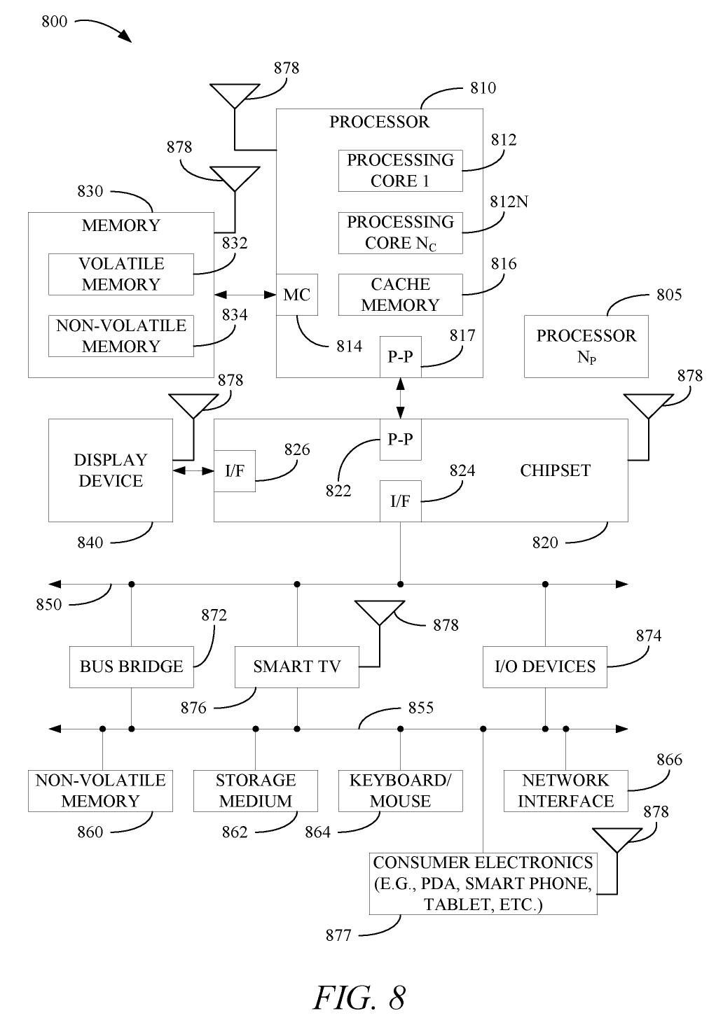

FIG. 8 illustrates a system level diagram, according to one embodiment of the invention. For instance, FIG. 8 depicts an example of an electronic device (e.g., system) including the microelectronics package 100 or the signaling system as described herein with reference to FIGS. 1-6B. FIG. 8 is included to show an example of a higher level device application for the present invention. In one embodiment, system 800 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 800 is a system on a chip (SOC) system.

In one embodiment, processor 810 has one or more processing cores 812 and 812N_{c}, where 812N_{c} represents the Nth processor core inside processor 810 where N_{c} is a positive integer. In one embodiment, system 800 includes multiple processors including 810 and 805, where processor 805 has logic similar or identical to the logic of processor 810. In some embodiments, processing core 812 includes, but is not limited to, pre-fetch logic to fetch instructions, decode logic to decode the instructions, execution logic to execute instructions, and the like. In some embodiments, processor 810 has a cache memory 816 to cache instructions and/or data for system 800. Cache memory 816 may be organized into a hierarchical structure including one or more levels of cache memory.

In some embodiments, processor 810 includes a memory controller 814, which is operable to perform functions that enable the processor 810 to access and communicate with memory 830 that includes a volatile memory 832 and/or a non-volatile memory 834. In some embodiments, processor 810 is coupled with memory 830 and chipset 820. Processor 810 may also be coupled to an antenna 878 to communicate with any device configured to transmit and/or receive wireless signals. In one embodiment, the antenna interface 878 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 832 includes, but is not limited to, Synchronous Dynamic Random Access Memory (SDRAM), Dynamic Random Access Memory (DRAM), Rambus Dynamic Random Access Memory (RDRAM), and/or any other type of random access memory device. Non-volatile memory 834 includes, but is not limited to, flash memory, phase change memory (PCM), read-only memory (ROM), electrically erasable programmable read-only memory (EEPROM), or any other type of non-volatile memory device.

Memory 830 stores information and instructions to be executed by processor 810. In one embodiment, memory 830 may also store temporary variables or other intermediate information while processor 810 is executing instructions. In the illustrated embodiment, chipset 820 connects with processor 810 via Point-to-Point (PtP or P-P) interfaces 817 and 822. Chipset 820 enables processor 810 to connect to other elements in system 800. In some embodiments of the invention, interfaces 817 and 822 operate in accordance with a PtP communication protocol such as the Intel® QuickPath Interconnect (QPI) or the like. In other embodiments, a different interconnect may be used.

In some embodiments, chipset 820 is operable to communicate with processor 810, 805, display device 840, and other devices 872, 876, 874, 860, 862, 864, 866, 877, etc. Chipset 820 may also be coupled to an antenna 878 to communicate with any device configured to transmit and/or receive wireless signals.

Chipset 820 connects to display device 840 via interface (I/F) 826. Display 840 may be, for example, a liquid crystal display (LCD), a plasma display, cathode ray tube (CRT) display, or any other form of visual display device. In some embodiments of the invention, processor 810 and chipset 820 are merged into a single SOC. In addition, chipset 820 connects to one or more buses 850 and 855 that interconnect various elements 874, 860, 862, 864, and 866. Buses 850 and 855 may be interconnected together via a bus bridge 872. In one embodiment, chipset 820 couples with a non-volatile memory 860, a mass storage device(s) 862, a keyboard/mouse 864, a network interface 866, smart TV 876, consumer electronics 877, etc., via interface 824.

In one embodiment, mass storage device 862 includes, but is not limited to, a solid state drive, a hard disk drive, a universal serial bus flash memory drive, or any other form of computer data storage medium. In one embodiment, network interface 866 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 8 are depicted as separate blocks within the system 800, the functions performed by some of these blocks may be integrated within a single semiconductor circuit or may be implemented using two or more separate integrated circuits. For example, although cache memory 816 is depicted as a separate block within processor 810, cache memory 816 (or selected aspects of 816) can be incorporated into processor core 812.

### Additional Notes & Examples

Example 1 is a signaling system comprising: a first die, a second die, a transmitter configured to transmit M signals, the transmitter electrically connected to the first die; a receiver configured to receive the M signals, the receiver electrically connected to the receiver; and a package interconnect including a bundle of N wires electrically connecting the transmitter and the receiver, wherein, during operation, the N wires of the bundle of N wires are electromagnetically coupled with each other and the M signals travel between the transmitter and the receiver on the bundle of N wires, wherein M is greater than 2, wherein N is greater than 3.

In Example 2, the subject matter of Example 1 optionally includes wherein the bundle of N wires has an average wiring density of at least 100 wires per mm.

In Example 3, the subject matter of any one or more of Examples 1-2 optionally include wherein M is greater than 20.

In Example 4, the subject matter of any one or more of Examples 1-3 optionally include wherein N is greater than 30.

In Example 5, the subject matter of any one or more of Examples 1-4 optionally include wherein M is less than or equal to N.

In Example 6, the subject matter of any one or more of Examples 1-5 optionally include wherein the bundle of N wires is a subset of a plurality of bundles of wires.

In Example 7, the subject matter of any one or more of Examples 1-6 optionally include wherein the bundle of N wires includes each of the bundle of N wires spaced proximate one another to promote electromagnetic coupling between each of the N wires of the bundle.

In Example 8, the subject matter of any one or more of Examples 1-7 optionally include wherein the package interconnect includes at least one of a silicon bridge, a silicon interposer, a fan-out wafer level package interconnect, a fan-out panel level package interconnect, and an organic dense multichip package interconnect.

In Example 9, the subject matter of any one or more of Examples 1-8 optionally include a bundle of W wires electrically connecting the transmitter and the receiver, wherein the W wires of the bundle are electromagnetically coupled with each other and are configured to carry X signals, wherein X is greater than 2, wherein W is greater than 3.

In Example 10, the subject matter of Example 9 optionally includes wherein a spacing between the bundle of N wires and the bundle of W wires is maximized to reduce electromagnetic coupling between the bundle of N wires and the bundle of W wires.

In Example 11, the subject matter of any one or more of Examples 1-10 optionally include a second transmitter; a second receiver; and a bundle of W wires embedded within the package interconnect and electrically connecting the second transmitter and the second receiver, wherein, during operation, the W wires of the bundle are electromagnetically coupled with each other and X signals travel between the second transmitter and the second receiver on the bundle of W wires, wherein X is greater than 2, wherein W is greater than 3.

In Example 12, the subject matter of Example 11 optionally includes wherein a spacing between the bundle of N wires and the bundle of W wires is maximized to reduce electromagnetic coupling between the bundle of N wires and the bundle of W wires.

In Example 13, the subject matter of any one or more of Examples 1-12 optionally include wherein the N wires of the bundle are distributed over a plurality of layers.

In Example 14, the subject matter of Example 13 optionally includes wherein the bundle of N wires has an average wiring density of at least 100 wires per mm per layer.

Example 15 is a signaling system comprising: a first die, a second die, means for transmitting M signals electrically coupled to the first die; means for receiving the M signals electrically coupled to the second die; and means for bundling N wires, the N wires electrically connecting the transmitting means and the receiving means, wherein, during use, the N wires are electromagnetically coupled with each other and the M signals travel between the transmitting means and the receiving means on the bundle of N wires, wherein M is greater than 2, wherein N is greater than 3.

In Example 16, the subject matter of Example 15 optionally includes wherein the bundle of N wires has an average wiring density of at least 100 wires per mm.

In Example 17, the subject matter of any one or more of Examples 15-16 optionally include wherein M is greater than 20.

In Example 18, the subject matter of any one or more of Examples 15-17 optionally include wherein N is greater than 30.

In Example 19, the subject matter of any one or more of Examples 15-18 optionally include wherein M is less than or equal to N.

In Example 20, the subject matter of any one or more of Examples 15-19 optionally include wherein the N wires are a subset of a plurality of wires.

In Example 21, the subject matter of any one or more of Examples 15-20 optionally include wherein the N wires include each of the N wires spaced proximate one another to promote electromagnetic coupling between each of the N wires.

In Example 22, the subject matter of any one or more of Examples 15-21 optionally include means for bundling W wires, the W wires electrically connecting the transmitting means and the receiving means, wherein, during use, the W wires are electromagnetically coupled with each other and X signals travel between the transmitting means and the receiving means on the bundle of W wires, wherein X is greater than 2, wherein W is greater than 3.

In Example 23, the subject matter of Example 22 optionally includes wherein a spacing between the N wires and the W wires is maximized to reduce electromagnetic coupling between the N wires and the W wires.

In Example 24, the subject matter of any one or more of Examples 15-23 optionally include means for transmitting X signals; means for receiving the X signals; and means for bundling W wires, the W wires electrically connecting the means for transmitting the X signals and the means for receiving the X signals, wherein, during use, the W wires are electromagnetically coupled with each other and X signals travel between the transmitting means and the receiving means on the bundle of W wires, wherein X is greater than 2, wherein

W is greater than 3.

In Example 25, the subject matter of Example 24 optionally includes wherein a spacing between the N wires and the W wires is maximized to reduce electromagnetic coupling between the N wires and the W wires.

Example 26 is a method for manufacturing a signaling system, the method comprising: forming a package interconnect; forming a bundle of N wires within the package interconnect, the bundle of N wires spaced such that during use, the bundle of N wires are electromagnetically coupled with each other; connecting a transmitter to the bundle of N wires, the transmitter configured to transmit M signals via the bundle of N wires; connecting a first die to the transmitter; connecting a receiver to the bundle of N wires, the receiver configured to receive the M signals via the bundle of N wires; and connecting a second die to the receiver, wherein M is greater than 2, wherein N is greater than 3.

In Example 27, the subject matter of Example 26 optionally includes wherein forming the package interconnect includes forming the bundle of N wires with an average wiring density of at least 100 wires per mm.

In Example 28, the subject matter of any one or more of Examples 26-27 optionally include wherein forming the bundle of N wires includes forming more than three wires within a single layer of the package interconnect.

In Example 29, the subject matter of any one or more of Examples 26-28 optionally include wherein forming the bundle of N wires includes forming the bundle of N wires as a subset of a plurality of bundles of wires.

In Example 30, the subject matter of any one or more of Examples 26-29 optionally include forming a bundle of W wires within the package interconnect, the W wires of the bundle spaced such that during use, the W wires of the bundle are electromagnetically coupled with each other; connecting the transmitter to the bundle of W wires, the transmitter further configured to transmit X signals via the bundle of W wires; and connecting the receiver to the bundle of W wires, the receiver further configured to receive the X signals via the bundle of W wires, wherein X is greater than 2, wherein W is greater than 3.

In Example 31, the subject matter of any one or more of Examples 26-29 optionally include forming a bundle of W wires within the package interconnect, the W wires of the bundle spaced such that during use, the W wires of the bundle are electromagnetically coupled with each other; connecting a second transmitter to the bundle of W wires, the second transmitter configured to transmit X signals via the bundle of W wires; and connecting a second receiver to the bundle of W wires, the second transmitter configured to receive the X signals via the bundle of W wires, wherein X is greater than 2, wherein W is greater than 3.

In Example 32, the subject matter of any one or more of Examples 30 or 31 optionally include wherein forming the bundle of N wires and forming the bundle of W wires include forming the bundle of N wires and forming the bundle of W wires to maximize a space between the bundle of N wires and the bundle of W wires to reduce electromagnetic coupling between the bundle of N wires and the bundle of W wires during use.

In Example 33, the subject matter of any one or more of Examples 26-32 optionally include wherein forming the bundle of N wires includes forming the bundle of N wires over a plurality of layers.

In Example 34, the subject matter of Example 33 optionally includes wherein the bundle of N wires has a wiring density of at least 100 wires per mm per layer.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplate are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. However, the claims may not set forth features disclosed herein because embodiments may include a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

1-25. (canceled)

26. A signaling system comprising:
a first die;
a second die;
a transmitter configured to transmit M signals, the transmitter electrically connected to the first die, wherein M is greater than 2;
a receiver configured to receive the M signals, the receiver electrically connected to the second die; and
a package interconnect including a bundle of N wires electrically connecting the transmitter and the receiver, wherein N is greater than 3,
wherein, during operation, the bundle of N wires are electromagnetically coupled with each other and the M signals travel between the transmitter and the receiver on the bundle of N wires.

27. The signaling system of claim 26, wherein the bundle of N wires has an average wiring density of at least 100 wires per mm.

28. The signaling system of claim 26, wherein M is greater than 20.

29. The signaling system of claim 26, wherein N is greater than 30.

30. The signaling system of claim 26, wherein M is less than or equal to N.

31. The signaling system of claim 26, wherein the bundle of N wires is a subset of a plurality of bundles of wires.

32. The signaling system of claim 26, wherein the bundle of N wires includes each of the N wires spaced proximate one another to promote electromagnetic coupling between each of the N wires.

33. The signaling system of claim 26, wherein the package interconnect includes at least one of a silicon bridge, a silicon interposer, a fan-out wafer level package interconnect, a fan-out panel level package interconnect, and an organic dense multichip package interconnect.

34. The signaling system of claim 26, further comprising a bundle of W wires electrically connecting the transmitter and the receiver, wherein the W wires are electromagnetically coupled with each other and are configured to carry X signals, wherein W is greater than 3 and wherein X is greater than 2.

35. The signaling system of claim 26, further comprising:
a second transmitter;
a second receiver; and
a bundle of W wires embedded within the package interconnect and electrically connecting the second transmitter and the second receiver, wherein W is greater than 3,
wherein, during operation, the W wires are electromagnetically coupled with each other and X signals travel between the second transmitter and the second receiver on the bundle of W wires, wherein X is greater than 2.

36. The signaling system of claim 35, wherein a spacing between the bundle of N wires and the bundle of W wires is maximized to reduce electromagnetic coupling between the bundle of N wires and the bundle of W wires.

37. The signaling system of claim 26, wherein the N wires of the bundle of N wires are distributed over a plurality of layers.

38. The signaling system of claim 37, wherein the bundle of N wires has an average wiring density of at least 100 wires per mm per layer.

39. A signaling system comprising:
a first die;
a second die;
means for transmitting M signals electrically coupled to the first die, wherein M is greater than 2;
means for receiving the M signals electrically coupled to the second die; and
means for bundling N wires, the N wires electrically connecting the transmitting means and the receiving means, wherein N is greater than 3,
wherein, during use, the N wires are electromagnetically coupled with each other and the M signals travel between the transmitting means and the receiving means on the bundle of N wires.

40. The signaling system of claim 39, wherein the bundle of N wires has an average wiring density of at least 100 wires per mm.

41. The signaling system of claim 39, wherein M is less than or equal to N.

42. The signaling system of claim 39, further comprising means for bundling W wires, the W wires electrically connecting the transmitting means and the receiving means, wherein, during use, the W wires are electromagnetically coupled with each other and X signals travel between the transmitting means and the receiving means on the bundle of W wires, wherein W is greater than 3, wherein X is greater than 2.

43. The signaling system of claim 39, further comprising:
means for transmitting X signals, wherein X is greater than 2;
means for receiving the X signals; and
means for bundling W wires, the W wires electrically connecting the means for transmitting the X signals and the means for receiving the X signals, wherein W is greater than 3,
wherein, during use, the W wires are electromagnetically coupled with each other and X signals travel between the transmitting means and the receiving means on the bundle of W wires.

44. The signaling system of claim 43, wherein a spacing between the N wires and the W wires is maximized to reduce electromagnetic coupling between the N wires and the W wires.

45. A method for manufacturing a signaling system for use in a dense interconnect, the method comprising:
forming a package interconnect;
forming a bundle of N wires within the package interconnect, the bundle of N wires spaced such that during use, the bundle of N wires are electromagnetically coupled with each other, wherein N is greater than 3;
connecting a transmitter to the bundle of N wires, the transmitter configured to transmit M signals via the bundle of N wires, wherein M is greater than 2;
connecting a first die to the transmitter;
connecting a receiver to the bundle of N wires, the receiver configured to receive the M signals via the bundle of N wires; and
connecting a second die to the receiver.

46. The method of claim 45, wherein forming the bundle of N wires includes forming more than three wires within a single layer of the package interconnect.

47. The method of claim 45, wherein forming the bundle of N wires includes forming the bundle of N wires as a subset of a plurality of bundles of wires.

48. The method of claim 45, further comprising:
forming a bundle of W wires within the package interconnect, the W wires spaced such that during use, the \V wires are electromagnetically coupled with each other, wherein W is greater than 3;
connecting the transmitter to the bundle of W wires, the transmitter further configured to transmit X signals via the bundle of W wires, wherein X is greater than 2; and
connecting the receiver to the bundle of W wires, the receiver further configured to receive the X signals via the bundle of W wires.

49. The method of claim 45, further comprising:
forming a bundle of W wires within the package interconnect, the W wires spaced such that during use, the W wires are electromagnetically coupled with each other, wherein W is greater than 3;
connecting a second transmitter to the bundle of W wires, the second transmitter configured to transmit X signals via the bundle of W wires, wherein X is greater than 2; and
connecting a second receiver to the bundle of W wires, the second transmitter configured to receive the X signals via the bundle of W wires.

50. The method of claim 49, wherein forming the bundle of N wires and forming the bundle of W wires include forming the bundle of N wires and forming the bundle of W wires to maximize a space between the bundle of N wires and the bundle of W wires to reduce electromagnetic coupling between the bundle of N wires and the bundle of W wires during use.
